(19) United States
(12) Patent Application Publication
(10) Pub. No.: US 2002/0111277 A1
(43) Pub. Date: Aug. 15, 2002

(54) Oxide superconductor composite having smooth filament-matrix interface

(76) Inventors: Alexander Otto, Chelmsford, MA (US); Ronald D. Parrella, Holden, MA (US)

Correspondence Address: HALE AND DORR, LLP, 60 STATE STREET, BOSTON, MA, 02109

(21) Appl. No.: 09/953,813

(22) Filed: Sep. 17, 2001

Related U.S. Application Data
(60) Provisional application No. 60/232,734, filed on Sep. 15, 2000.

(51) Int. Cl. H01L 39/00; C10F 5/00; C04B 2/00; H01F 1/00; H01B 1/00

(52) U.S. Cl. 505/825

(57) ABSTRACT

A method of making an oxide superconductor article includes providing an oxide filament comprising a textured oxide superconductor precursor having an effective oxide flow stress, (σ_{c}, in a silver-based matrix, and converting the textured oxide superconductor precursor into an oxide superconductor. During precursor conversion, a compression stress is applied to the oxide filament which is greater than or equal to the oxide flow stress (σ_{c}), the silver-based matrix having a flow stress, σₛ, whereby σₛ>σ_{c} under conditions of phase conversion so that material flow between the silver-based matrix and the oxide filament is substantially avoided. An oxide superconductor may also be prepared by converting at least a portion of the textured oxide superconductor precursor into an oxide superconductor, whereby porosity is introduced into the oxide filament, and applying a compression stress to the oxide filament that is greater than the oxide flow stress, σ_{c}, to densify the porous oxide superconductor, whereby σₛ>σ_{c} under densifying conditions so that material flow between the silver-based matrix and the oxide filament is substantially avoided.

### RELATED APPLICATIONS

This application is a continuation-in-part application of and claims priority under 35 U.S.C. §119(e) from U.S. Ser. No. 60/232,734, filed Sept. 15, 2000, entitled “Oxide Superconductor Composite Having Smooth Filament-Silver Interface,” which is hereby incorporated by reference.

This application is related to co-pending application, entitled “Superconducting Article Having Low AC Loss”, filed on even date herewith, and hereby incorporated by reference.

### BACKGROUND OF THE INVENTION

This invention relates to processing of oxide superconductor composites to obtain high density, textured oxide superconductor articles. In particular, the invention relates to formation of high density, well-textured oxide superconductor filaments bounded by smooth matrix-oxide interfaces.

Polycrystalline, randomly oriented oxide superconductor materials are generally characterized by low density and low critical current densities. High oxide density, good oxide grain alignment and grain interconnectivity, however, are associated with superior superconducting properties.

Composites of superconducting materials and metals are often used to obtain better mechanical properties than superconducting materials alone provide. These composites may be prepared in elongated forms such as wires and tapes by the well known “powder-in-tube” or “PIT” method. When powders include metal oxides or other oxidized metal salts, the method is referred to as “oxide-powder-in-tube” or OPIT. For multifilamentary articles, the method generally includes the three stages of (a) forming a powder of superconducting precursor materials (precursor powder formation stage), (b) filling a noble metal billet with the precursor powder, longitudinally deforming and annealing it, forming a bundle of billets or of previously formed bundles, and longitudinally deforming and annealing the bundle to provide a composite of reduced cross-section including one or more filaments of superconductor precursor material surrounded by a noble metal matrix (composite forming stage); and (c) subjecting the composite to successive asymmetric deformation and annealing cycles and further thermally processing the composite to form and sinter a core material having the desired superconducting properties (thermomechanical processing stage). General information about the OPIT method described above and processing of the oxide superconductors is provided by Sandhage et al. in JOM, Vol. 43, No. 3 (1991), pp. 21-25, and references cited therein; by Tenbrink et al., “Development of Technical High-Tc Superconductor Wires and Tapes”, Paper MF-1, Applied Superconductivity Conference, Chicago (Aug. 23-28, 1992); and by Motowidlo et al., “Properties of BSCCO Multifilament Tape Conductors,” Materials Research Society Meeting, Apr. 12-15, 1993, all of which are incorporated by reference.

The deformations of the thermomechanical processing state are asymmetric deformations, such as rolling and pressing, which create alignment of precursor grains in the core (“textured” grains) and facilitate the growth of well-aligned and sintered grains of the desired oxide superconducting material during the later thermal processing stages. A series of heat treatments is typically performed during the thermomechanical processing stage to fully convert the filaments to the desired highly textured superconducting phase. Such heat treatments may occur after deformation processing has aligned precursor oxide grains. When heating during the thermomechanical processing stage, the oxide grains experience dilation leading to reduced oxide core density and increased porosity of the oxide core. The sources of dilation and hence, the understanding of the expansion forces working on the oxide composite, are complex.

Current approaches to rectifying the de-densification arising from the thermal process include mechanical deformation to redensify the oxide material. Typically, an “intermediate” deformation step, normally a rolling operation, is applied after partial i.e., 70-95%, formation of the final oxide superconductor. This step serves to collapse the porous, partially sintered oxide grains thereby increasing density and oxide texture. It also serves other positive functions, such as providing cracks and other reactive surfaces that promote reaction to a final oxide superconductor. However, intermediate rolling also leads to degradation of the smooth, planar interface between the silver matrix and the oxide filament, leading to a roughening of the silver/oxide superconductor interface. Rough matrix-oxide interfaces are associated with nucleation and growth of poorly aligned oxide superconductor grains that limit the critical current of the filament.

In a multifilamentary silver composite, Bi₂Sr₂Ca₂Cu₃Oₓ (Bi-2223) grains grow with c-axis normal to the local silver-filament interface surface. As used herein, “x” is an amount to provide superconductivity at cryogenic temperatures. Dense, textured Bi-2223 nucleates and/or grows faster and better in close proximity to silver. When the silver-filament interface is smooth, the interface plane assists in aligning the Bi-2223 grains with their high current direction (a-b plane) along the direction of the filament and tape axis. However, if the interface is rough or uneven, then small amounts of poorly aligned Bi-2223 grains can grow through the filament at angles offset from the direction of the filament and tape axis, occluding much larger fractions of filament area than the volume fractions they occupy and thereby significantly degrading J_{c}. Although overall Bi-2223 texture is improved with the OPIT method, J_{c} gains are minimal due, in part, to the presence of this low volume fraction of poorly aligned Bi-2223.

Conventional powder processing of oxide superconductor composites has not succeeded in eliminating silver-oxide interface roughness. There remains a need to reduce or prevent the incidence of misaligned Bi-2223 grains in the final superconducting composite article.

There remains a further need for a highly textured and dense oxide superconductor composite lacking surface roughness or other irregularities at the silver-oxide interface.

### SUMMARY OF THE INVENTION

These and other limitations of the prior art are overcome by the present invention, which is directed to a dense, highly textured oxide superconductor having a smooth (non-roughened) oxide-silver matrix interface. The formation of oxide superconductor composites without interfacial oxide-silver surface roughening aids in the reduction or prevention of grain misalignment in the final oxide superconducting composite article and avoids oxide core dilation and associated grain misalignment. The process also avoids material flow or creep of the silver matrix during thermal phase conversion or during deformation processing.

In one aspect of the invention, an oxide filament including a textured oxide superconductor precursor having an effective oxide flow stress, σ_{c}, in a silver-based matrix having a flow stress, σₛ, greater than that of pure silver is provided, and converted into an oxide superconductor. During precursor conversion, a compression stress is applied to the precursor which is greater than or equal to the oxide flow stress, σ_{c}, whereby σₛ>σ_{c} under conditions of phase conversion so that material flow of the silver-based matrix into the oxide filament is substantially avoided. In at least some embodiments, the externally provided compression stress at least matches the expansion force experienced by the precursor during conversion to the oxide superconductor.

In another aspect of the invention, an oxide filament including a textured oxide superconductor precursor, having an effective oxide flow stress, σ_{c}, in a silver-based matrix having a flow stress, σₛ, greater than that of pure silver is converted into an oxide superconductor in a process that introduces porosity into the oxide filament. A compression stress that is at least greater than the oxide flow stress, σ_{c}, is applied to the precursor to densify the porous oxide superconductor filament, whereby σₛ>σ_{c} under densifying conditions so that material flow between the silver-based matrix and the oxide filament is substantially avoided.

In at least some embodiments, the silver-based matrix is converted into a matrix having a selected flow stress, σₛ, greater than that of pure silver, either before or during precursor conversion.

In at least some embodiments, a compression stress is applied to the oxide filament to densify the oxide superconductor after phase conversion of at least a portion of the precursor to the oxide superconductor. The compression stress is at least greater than the oxide flow stress, σ_{c}, and may be greater than the matrix flow stress, σₛ.

In at least some embodiments, the flow stress of the silver-based matrix is obtained by formation of strengthening agents which increase the flow stress, σₛ, of the material over that of pure silver. In at least some embodiments, the strengthening agents comprise fine oxide particles. In at least some embodiments, the silver-based matrix includes a silver alloy comprising solute metals, and the step of converting the silver-based matrix into a matrix having a selected flow stress, σₛ, includes oxidizing the solute metals into metal oxides. The oxidizing step may be carried out at a temperature in the range of 200-450° C. in an oxidizing atmosphere, or at a temperature in the range of 200-300° C. in an oxygen partial pressure in the range of up to about 500 atm.

In at least some embodiments, the predecessor metals are selected from the group consisting of aluminum and magnesium. In at least some embodiments, the solute metal is present in an amount in the range of about 0.15 wt % to about 1.5 wt %.

In at least some embodiments, the compression force applied to the precursor includes uniaxial pressing or mechanical constraint. The step of applying a mechanical constraint includes positioning the oxide filament between opposing surfaces to provide a compressive force, or co-winding the oxide filament with an elongated element, so that the elongated element is wound under tension to provide a compressive force. In at least some embodiments, the compression stress applied to the precursor comprises hot isostatic pressing (HIPing). In at least some embodiments, the HIPing force is in the range of 10 to 2500 atm, or in the range of 25 to 250 atm. In at least some embodiments, the silver-based matrix includes a solute metal in the range of about 1.5 wt %.

In at least some embodiments, the compression stress applied to the precursor includes rolling. The silver-based matrix may include a solute metal in the range of about 0.15 wt %. The rolling compression results in a 5-20% reduction in thickness of the article.

In at least some embodiments of the invention, the density of the oxide superconductor precursor is substantially retained during conversion to the oxide superconductor. In at least some embodiments, the texture of the oxide superconductor precursor is substantially retained during conversion to the oxide superconductor. In at least some embodiments, the precursor may be textured using asymmetric deformation, or the asymmetric deformation may be selected from the group consisting of rolling and pressing, or the rolling deformation may result in a 40-95% reduction in thickness of the article, or the precursor is textured using reaction-induced texturing.

In at least some embodiments, the precursor oxide includes Bi-2212, and the final oxide superconductor includes Bi-2223. The precursor may include Bi-2212 and reaction induced texturing is conducted at a temperature in the range of 800-860° C. and an oxygen partial pressure in the range of 0.01-1.9 atm. Bi-2212 may be converted into Bi-2223 in a two-step heat treatment in which the precursor is heated under conditions that form a liquid phase in co-existence with Bi-2223 and then the precursor is heated under conditions which transform the liquid phase into Bi-2223.

In another aspect of the invention, a Bi-2223 oxide superconductor article is provided which includes at least one oxide superconducting filament in a silver-based matrix, wherein the matrix-filament interface has an average deviation from planarity of less then 10° along the length of the filament.

In at least some embodiments, the filament length is at least one cm, or the filament length is at least 10 cm, or the filament length is at least 100 cm.

“Flow stress” is used herein to mean the threshold level of stress which, when exceeded, results in material flow. In the case of an oxide superconductor, such flow may be considered to be movement of the oxide grains relative to one another. A related material property is “creep,” which is the flow or plastic deformation of metals held for long periods of time at stresses lower than the normal yield strength. The effect is particularly important if the temperature of stressing is in the vicinity of the recrystallization temperature of the metal.

Surface finish may be defined in terms of small scale and large scale features. “Surface roughness” at the matrix metal-oxide interface refers to a local geometry (small-scale) of the filament on the order of an superconductor oxide grain size, e.g., about 1 to 30 μm, and more particularly about 10-20 μm. The oxide surface is considered “smooth” according to the invention when the grain-to-grain misorientation of the oxide grains at the matrix-oxide interface along the direction of current flow is no greater than about 10-12°, or when the average deviation of grain-to-grain misorientation is less than about 10-12°. The angle of misorientation is determined by the angle of intercept between the two misoriented planes, as is shown in FIG. 1.

Surface “roughness” (and “smoothness”) refers to a local geometry of the filament and is not to be equated with “sausaging.” Sausaging is a large-scale surface feature defined over longer lengths of the filament surface. Sausaging is a consequence of the differences in flow properties of the oxide core and the silver matrix during initial forming and texturing operations, leading to periodic widening and narrowing of the filament width. Methods for reducing sausaging are described in U.S. Pat. No. 6,247,089, entitled “Simplified Deformation-Sintering Process for Oxide Superconducting Articles.”

“Precursor filament” or “precursor oxide composite” is used herein to mean the precursor oxide composite, e.g., Bi-2212 and secondary phases, which has been processed to form a filamentary composite. The precursor composite is characterized by high density, a high degree of texture and smooth silver matrix-oxide filament interfaces, features that the present invention maintains on conversion of the precursor to the final oxide superconductor.

“Dilation” is the loss of core material density due to introduction of pore space and/or changes in grain size and structure.

“Partially sintered” or “partially reacted” oxide composite is used herein to mean the oxide composite after thermal heat treatment to convert at least a portion of the precursor oxide into the final oxide superconductor, e.g., Bi-2223. The partially sintered or partially reacted composite contains both Bi-2212 precursor and Bi-2223 final oxide superconductor. The composite is characterized by porosity brought about by Bi-2223 grain growth, and the Bi-2223 grains may be sintered at contact points.

### BRIEF DESCRIPTION OF THE DRAWING

The invention is described with reference to the following Figures, which are presented for the purpose of illustration only and which are not limiting of the invention, and in which:

FIG. 1 demonstrates the determination of the angle of misorientation for oxide grains in the oxide superconductor filament;

FIGS. 2-4 illustrate the microstructural evolution at the silver matrix-oxide interface of the final oxide superconductor in a filament tape;

FIG. 5 is a cross-sectional illustration of the microstructure of a fully reacted Bi-2223 oxide filament composite;

FIG. 6 is a perspective drawing of one mode of mechanical constraint used in the practice of the invention;

FIG. 7 is an illustration of one mode of mechanical constraint used for continuous lengths of wire in the practice of the invention; and

FIG. 8 is a plot of Je dependence on intermediate strain reduction (ISR) deformation, using pack or bare rolling and pressing, for (A) F50a1 (Jc=4×Je) and for (B) F50b2 (Jc=2.3×Je).

### DETAILED DESCRIPTION OF THE INVENTION

A method is described to avoid or minimize interfacial surface roughness during formation of oxide superconductor multifilamentary articles, and in particular, during steps involving oxide dilation. An oxide super conducting composite is described having reduced interfacial surface roughening, smooth oxide surfaces and reduce oxide grain misalignment.

In most cases, the oxide precursor to the final oxide superconductor will be made up of a mixture of phases, in which the overall stoichiometry of the phases substantially corresponds to that of the final oxide superconductor. While the oxide precursor is desirably highly textured and dense, its grain size and morphology are different than those of the final oxide superconductor. Consumption of the precursor phases and growth of the final oxide superconductor can lead to void spaces within the composite (as material is consumed to make the oxide superconductor) and grain elongation (as the oxide precursor grains react with other secondary phases to form the final oxide superconductor). As they grow, the grains push apart neighboring grains in their path. The combination of void formation and grain elongation results in a significant expansion of the oxide phase with a concomitant reduction in density, texture and electrical transport.

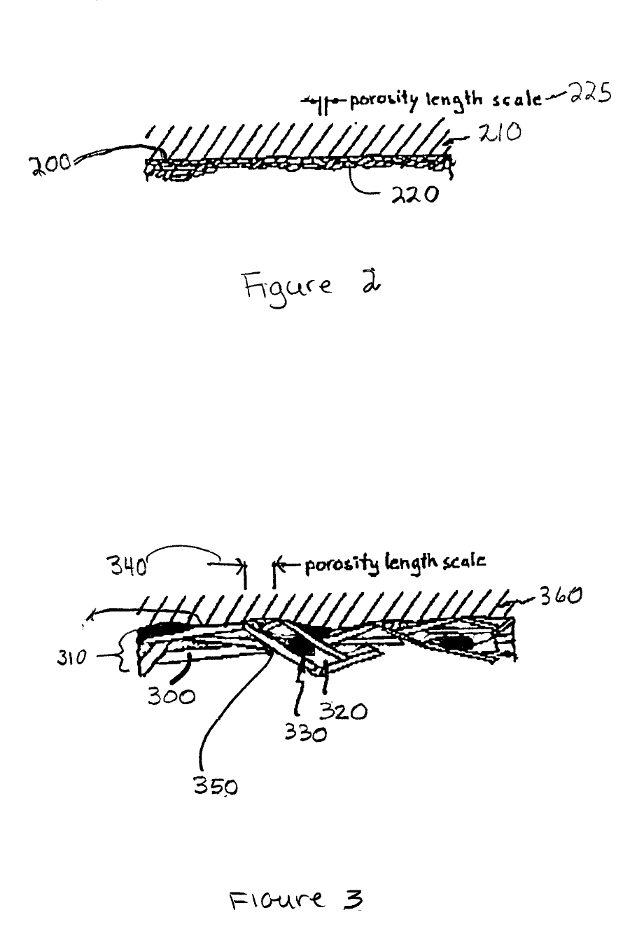

The microstructural evolution of an oxide superconductor is described in greater detail for (Pb,Bi)₂Sr₂Ca₂Cu₃Oₓ(Bi-2223) oxide superconductor in a multifilament tape with reference to FIG. 2. The process is described with reference to the Bi—Sr—Ca—Cu—O (BSCCO) family of oxide superconductors, but it is understood that the description that follows may be applied to other superconducting systems having an aspected morphology. It is particularly well suited for oxide superconducting systems having platy oxide grains.

Multifilamentary Bi-2223 oxide superconductor tapes are prepared from fine oxide precursor powders consisting of Bi₂Sr₂Ca₁Cu₂Oₓ (Bi-2212) and a mixture of reactant phases (“0011”) containing calcium, copper and lead (Ca²⁺, Cu³⁺, Pb^{2+,4+}), as well as Sr and Bi, which are packed into silver tubes and deformed into monocored filaments, typically hexagonally-shaped due to the high packing efficiency of the shape. These rods are cut into pieces and rebundled inside silver sheaths that are deformation processed, e.g., drawn or extruded, into long multifilament wires.

Asymmetric deformation, such as sheet rolling, is used to align the c-axis planes of the Bi-2212 oxide grains. The extent of alignment is good—to within 10° of the rolling plane, as is shown in FIG. 2. Under ideal conditions, texture is conserved during conversion of the precursor oxide into the final oxide superconductor so that the final oxide superconductor is also highly textured. Although rolling increases core density, it can force silver into near-interface voids of the powder if the silver's flow stress, σₛ, is less than the oxide flow, σ_{c}, that is if the silver flows before the externally applied stress can collapse and texture the core. Despite the deformation forces experienced by the precursor composite, metal matrix-precursor oxide interface 200 remains fairly smooth at this point in the process. This is due, in part, to the fact that the forming process described in the previous paragraph results in work hardening of the silver matrix 210 so that the silver flow stress, σ_{c}, is high. Furthermore, the fine particle size of the precursor 220, e.g., 1-10 μm, and typically, 1-5 μm, enables efficient particle packing and low porosity (on the scale of about 1 micron), designated by arrows 225, giving rise to a low porosity structure that is not amenable to silver infiltration.

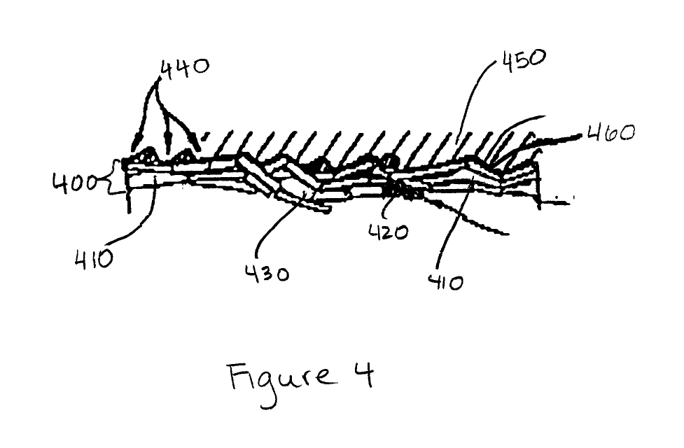

This situation changes, however, with further heat treatment, as is shown in FIG. 3. Typically, a 20-40 hour heat treatment at greater than 800° C. is used to mostly, e.g., ˜70-90%, convert the precursor oxide powders into Bi-2223. The Bi-2223 grains 300 grow along their edges in the a and b directions, pushing apart the oxide core 310 and forming void spaces 320 and regions of unreacted precursor oxide 330. The angle of misalignment θ may be very large, and in particular may be greater than about 10-12°. The porosity length scale, indicated by arrows 340, also increases significantly to greater than one micron, and typically is on greater than 5 μm. This heat treatment also sinters the precursor powder core so that Bi-2223 grains are sintered at contact points 350, which increases its hardness. Significantly, while hardening the oxide core, it also completely anneals and softens the silver matrix 360 to about ambient flow stress levels (˜2 ksi). Hardness tests on the sintered oxide core demonstrate that its flow stress (σ_{c}) is much greater than the flow stress (σₛ) of the silver matrix, that is, σₛ<<σ_{c}. The oxide-silver interface 320 still remains relatively smooth.

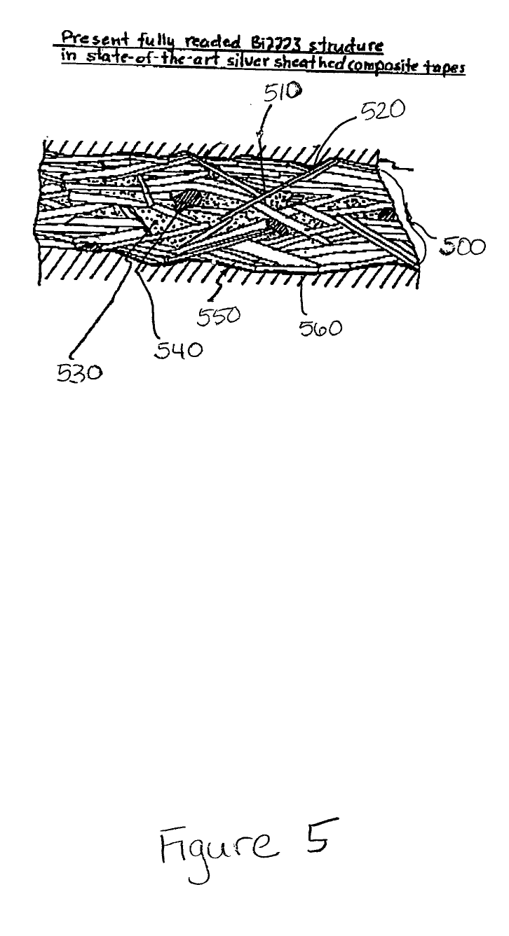

In conventional processes, heat treatment is followed by a low-strain (˜5-20%) intermediate rolling deformation at ambient temperature to counteract the negative effects of the phase converting heat treatment, namely, to increase core density, reduce porosity length scale and reactant phase sizes, and improve Bi-2223 texture by grain alignment. As shown in FIG. 4, the sintered core 400 includes partially oriented Bi-2223 grains 410, as well as unreacted precursor material 420 and void space 430. Unlike the as-rolled state shown in FIG. 2, the flow stress of the silver now is much less than the collapse stress of the oxide core so that the now dead-soft silver 450 readily flows under the rolling deformation forces into the near-interface void cavities 440 of the core before sufficient stress can be transferred through the silver from the deformation source to fracture and collapse the sintered core 400. This results in a rough interface 460 between the silver and oxide core. The rough interface is characterized by deviations from planarity along the filament length on the order of the oxide grain size at the matrix-filament interface and out-of-plane orientation of the Bi-2223 oxide grains.

A subsequent heat treatment is then applied to complete formation of the Bi-2223 oxide superconductor (˜95-98%) and to sinter the oxide grains. The microstructure of a fully reacted oxide core 500 shown in FIG. 5 typifies the poorly aligned Bi-2223 grains 510 that can project through the filament from out-of-plane bumpy silver-core interfaces regions 520. The filament center 530 is also typically more porous than the near interface region and may contain unreacted starting materials 540. Oxide grains 550 that grow from smooth interface regions 560 exhibit the desired c-axis alignment of the Bi-2223 grains. Although the overall c-plane texture is improved, occasional poorly aligned high aspect ratio Bi-2223 grains can occlude large parts of the local filament, resulting in a disproportionately deleterious effect on J_{c}. These grains grow from interface regions that are out of alignment with the overall filament plane, as is demonstrated by oxide grain 520 in FIG. 5.

The matrix-oxide core interfacial surface roughening occurs, in part, due to differences in the relative hardness of the matrix and the oxide core at key points in the processing of an oxide superconductor multifilament composite. Changes in matrix flow stress after work hardening operations used in the formation of the precursor multifilament article and after annealing operations used in the texturing of the precursor powders and in the formation of the oxide superconductor are addressed in the method of the present invention. The method accommodates differences in compression resistance between the fine-grained precursor oxide and the partially sintered, partially reacted Bi-2223 oxide core.

Methods and materials are provided for avoiding interfacial surface roughness, and thereby for obtaining a highly oriented, highly textured oxide superconductor composite. Material compositions and flow stress and oxide core stress conditions in the composite are selected that are compatible with the composite fabrication process, such that the matrix material does not penetrate the near-interface porosity of the oxide core during final oxide superconductor formation, and such that sufficient compression is applied to the oxide core to avoid or to reduce filament center porosity. These features help to avoid the misaligned Bi-2223 grains that project from the rough or bumpy interface and the filament center porosity illustrated in FIG. 5.

In order to avoid or minimize interfacial silver-oxide surface roughening (and the resultant misalignment of Bi-2223 grains), the silver matrix that is in contact with the oxide filaments may be modified so as to increase the flow stress of the matrix and/or to improve the creep resistance of the matrix at the elevated temperatures used in Bi-2223 formation. Specifically, the silver matrix is modified such that flow stress of the matrix is greater than flow stress of the oxide core during precursor conversion to the oxide superconductor and/or during intermediate deformations prior to full conversion of the precursor into the final oxide superconductor. Note that no absolute value for matrix flow stress is required, just that its value, relative to the oxide core, should be greater. The actual value for flow stress will vary depending on the processing conditions, e.g., temperature, and the point in the process at which densification occurs.

In one embodiment of the invention, the silver matrix flow properties are altered by the use of oxide dispersions that are formed in situ from reactive solute metal elements. The flow stress of silver at ambient may be increased by about an order of magnitude. Higher oxide levels can even extend silver's strength at temperatures above the formation temperature of Bi-2223 (creep stress).

In at least some embodiments, the dispersed oxides may be formed in a separate operation at low temperatures (250-450° C.). Oxide dispersion strengthening is ideally suited for silver because oxygen's unusually high diffusion rates in silver allow oxygen diffusion to all parts of the composite, so that oxidation of the dissolved solute metal may take place after most or all of the deformation processing of the composite is complete. Thus, the precursor oxide multifilamentary composite may be substantially completely textured using the asymmetric deformation processes described herein prior to formation of the oxide dispersion in the silver matrix. Because the oxide precursor possesses low filament porosity and the silver retains a high flow stress due to work hardening under formation conditions, no additional modification to the matrix is required at this point. In at least some embodiments, oxide dispersions in the silver matrix at this point in the process, since it may reduce matrix ductility, resulting in a brittle matrix.

Suitable solute metals are those that do not poison or undergo deleterious reactions with the oxide superconductor, which are effective in strengthening the silver matrix with low load levels of solute metal, and which do not result in a significant loss in matrix ductility. Exemplary solute metals include magnesium and aluminum, alone or in combination with yttrium or other rare earth elements. In at least some embodiments, magnesium and aluminum are the solute metals because they may be dissolved at high levels (to near saturation) without substantial loss of ductility. Addition of metal solutes desirably does not reduce the ductility of the silver matrix to a level that would prevent its use in the variety of forming operations necessary to form the multifilamentary article.

The presence of the oxide dispersion strengthened (ODS) silver is required only at the matrix-oxide filament interface, where the material flow of silver is likely to occur. Thus, the silver matrix composition may be varied, such that the ODS oxide content of the matrix immediately adjacent to the oxide filament differs from that of the matrix some distance from the oxide filaments. In at least some embodiments, the matrix may include a high flow stress ODS layer adjacent to the oxide filament, with pure silver or an ODS silver of another composition making up the remainder of the matrix. The matrix may, for example, include other additives to provide regions of high resistivity for reducing ac losses.

The level of oxide dispersion may be adjusted depending upon whether simple mechanical restraint or active compression is used in the process. Two oxide regimes have been identified, one in which ductility of the ODS silver, i.e., after oxidation, is sufficient to allow intermediate rolling and a second in which ductility is adequate for standard manipulations of the multifilamentary composite (i.e., bending, coiling, etc.) but which is too brittle for intermediate rolling.

In at least some embodiments employing an intermediate roll to densify the oxide core after dilating conversion to the final oxide superconductor, acceptable alloyed metal loads, i.e., wt % metal alloyed with silver prior to oxide formation, is in the range of about 0.01-0.5 wt %, and in at least some embodiments, alloyed metal loads are about 0.15-0.5 wt %. As used here, “alloyed metal” refers to the metal alloyed with silver prior to oxide formation, which is converted into metal oxide in a subsequent step. Weight percent or volume percent of resultant metal oxide will be different from that of the alloyed metal, but is readily determined from the starting alloyed metal content. In at least some embodiments, a metal load of about 0.2 wt % magnesium may be used.

In at least some embodiments employing a mechanical restraint during precursor conversion to prevent dilation or porosity, higher metal load levels are required due to the higher temperatures experienced by the silver matrix at the time of compression. The composite can tolerate the higher metal loads because it is not required to withstand deformation processes such as rolling or bending under mechanical constraint. The upper limit may be the metal load at which failure of the matrix occurs. In at least some embodiments, levels of up to about 1.5 wt % may be used (but this is not intended to suggest that this is the load limit to failure for any particular material).

The particle size of the dispersed oxide in the silver matrix also is relevant to its flow stress. Larger particles offer less resistance to flow than smaller particles. In at least some embodiments, the dispersed oxides are as small as possible. In at least some embodiments, the particle size is less than about 0.1 μm, or, in at least some embodiments, less than about 10 nm. Small particle sizes may be achieved by using low temperatures for oxidizing conditions, so as to avoid oxide coarsening.

In at least some embodiments, the oxide super conductor article is mechanically restrained (e.g., passively compression) or actively compressed during phase conversion of the oxide precursor into the final oxide superconductor. Mechanical restraint or active compression involves the application of an opposing force to the composite during precursor oxide conversion into the final oxide superconductor. In active compression, an external force is introduced to compress the oxide filaments. In passive compression, the system is constrained so that any dilation forces which may develop during phase conversion are opposed by the physical constraints of the system.

In either system, compression forces are being applied under phase converting conditions, that is, at elevated temperatures. This then requires that σₛ>σ_{c} even at the elevated temperatures used for Bi-2223 formation. The higher oxide contents in the range of about 1.5 wt % have been found to provide adequate matrix stress flow at Bi-2223 forming conditions. By applying a compressive force to the composite greater than σ_{c} during the time of Bi-2223 formation, the expansive forces on the composite are opposed and the dilation of the oxide core is prevented or reduced, i.e. the core can flow in response to the applied stress during phase formation. Thus, while the Bi-2223 oxide grains are growing, they are also subjected to an asymmetric force, which promotes c-axis alignment. Furthermore, by carrying out mechanically constrained phase conversion using a high flow stress matrix material, the silver matrix does not flow or creep under conditions in which the oxide does, the Bi-2223 formation conditions.

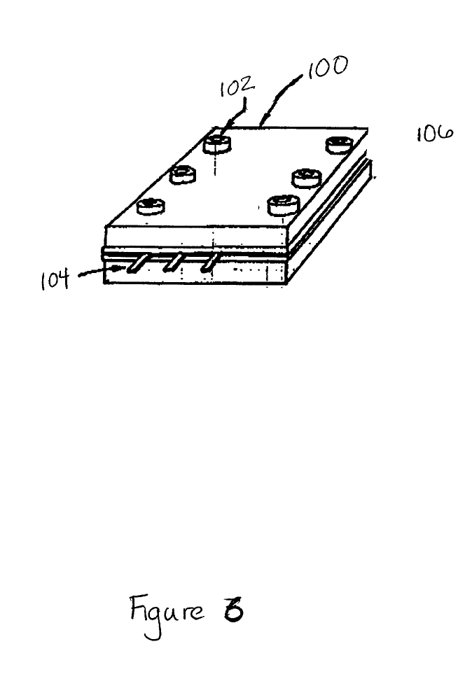

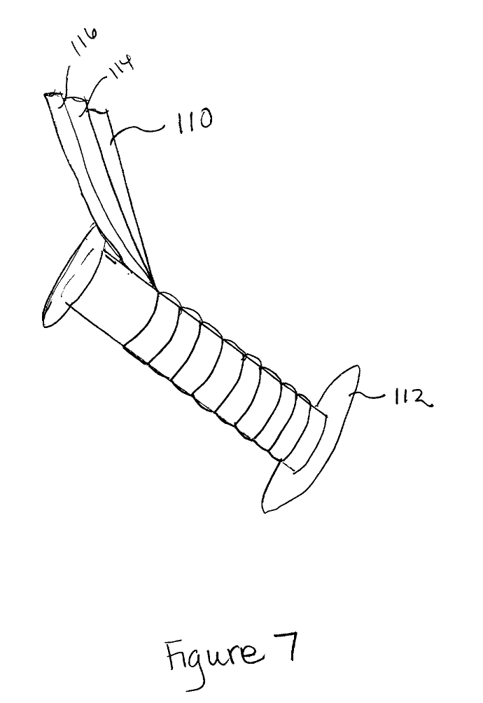

An exemplary, non-limiting method for mechanical constraint is shown in FIG. 6 consisting of Inconel® high temperature alloy plates 600 with screws 602 tightened to specific torque levels that generate the desired compression levels in the composite multifilamentary tapes 604 positioned between the tapes. A ceramic fiber matting 606, such as an oxygen permeable aluminum oxide matting (“SaffTi”), or other suitable material, is used as an interlayer on either side of the tapes which serves to prevent tape sintering to the alloy plates and to provide mechanical compliance. With the matting acting as the compressive medium, the multifilamentary tapes will remain at or about the compressive stress levels generated by the ambient temperature torque-down of the screws on the alloy plates. The sample may be constrained to a variety of torque and compressive stress levels in this manner. In at least some embodiments, uniaxial pressure, e.g., hot pressing, is applied to maintain density and texture in the plane or direction of elongation. Hot pressing is less preferred because it is not readily scalable to large manufacturing processes and because greater care must be taken to avoid overpressurizing, which may cause cracking in the article. Samples constrained as described above may be processed and tested to determine the appropriate compressive stress conditions at which porosity is essentially eliminated.

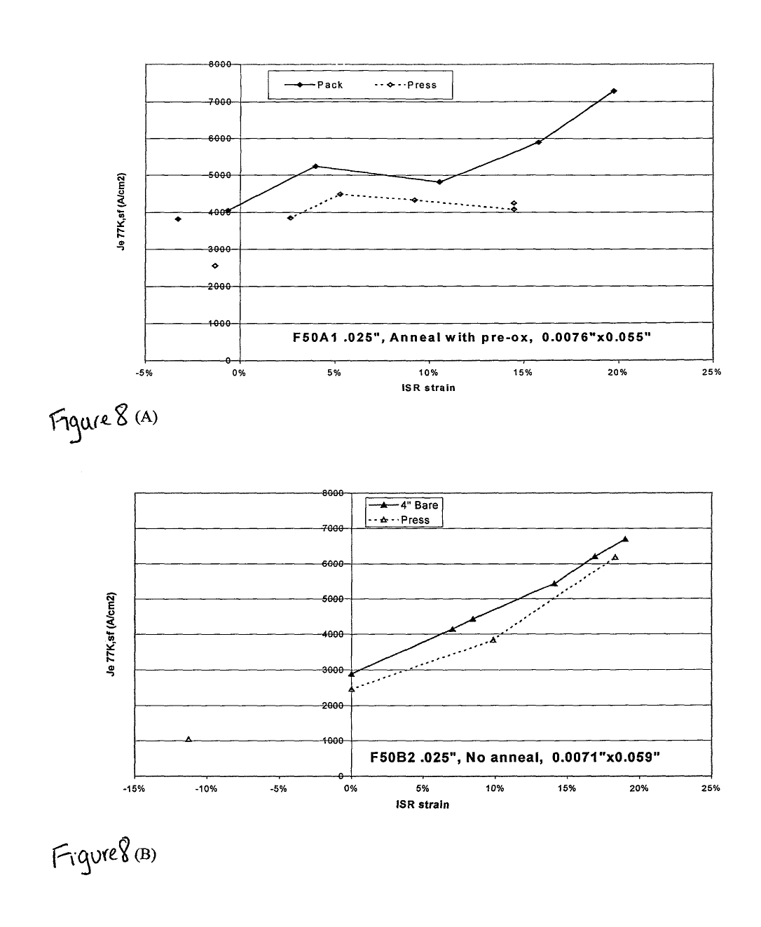

In a continuous or long length process, the as-rolled precursor tape 710 may be co-wound onto a mandrel or cassette 712 with an intermediate ceramic fiber matting 714 and high temperature alloy strip 716, as shown in FIG. 7. The tape, ceramic fiber matting and alloy strip are wound under tension to generate the desired levels of compressive stress on the tape. The compressive stress may be augmented by the use of additional outer high temperature windings that are applied under high tension. The sample may be constrained to a variety of torque and compressive stress levels in this manner.

A further method for mechanical restraint involves the use of isostatic pressure during phase conversion. This is accomplished by simultaneously applying a force to an oxide composition during phase conversion of the oxide to a final oxide superconductor. The force opposes the expansion force experienced by the composite during heat treatment or 2223 phase conversion to constrain the material and prevent dilation and de-densification. In at least some embodiments, an isostatic pressure is used as the constraining force. When used at elevated temperature conditions, the process is known as hot isostatic pressing (HIP). In at least some embodiments, pressures may be in the range of about 10-2500 atm (1-250 MPa), and in at least some embodiment about 25-100 atm (2.5-10 MPa). Improvements in density and texture retention during phase conversion have been observed for pressures in the range of about 40-85 atm (4-8.5 MPa). Pressure is applied at a temperature and an oxygen partial pressure that facilitates phase conversion of the precursor into the oxide superconductor. Further detail of the process is provided in United States copending application Ser. No. 09/655,882 filed Sept. 20, 2000, entitled “Simultaneous Constraint and Phase Conversion Processing of Oxide Superconductors,” which is hereby incorporated by reference.

In at least some embodiments, the compressive force is provided from an intermediate rolling operation. Intermediate rolling involves the application of a densifying force (5-20% reduction in thickness) to the dilated oxide core after thermal heat treatment to form the final oxide superconductor to increase core density, reduce porosity length scale and improve Bi-2223 texture. The intermediate rolling strain may be varied to find an optimum strain, such as by way of example, small strains using large diameter (<20 cm) rolls that deform more like uniaxial pressing. This allows the condition, σₛ>σ_{c}, to be satisfied at lower temperatures than for mechanical constraint, possibly as low as ambient. In at least some embodiments, oxide contents in the range of about 0.01-0.15 wt % metal solute have been found to provide adequate matrix stress flow under the intermediate rolling conditions. In at least some embodiments, the precursor composite or the partially sintered composite may be processed to reduce core flow stress to ensure that σₛ>σ_{c}. For example, the sintered oxide grains may be fractured prior to rolling. Any conventional means for fracturing the sintered oxide grains may be used, for example, high-energy ultrasonic vibrations. In at least some embodiments, the partially reacted multifilamentary tape may be passed through an ultrasonic bath prior to rolling.

In another aspect of the invention, oxide superconductor composites having a significantly reduced volume fraction of misaligned Bi-2223 grains are provided. Oxide superconductor composites exhibit increased volume fraction of aligned Bi-2223 grains when compared to similarly processed articles lacking the increased flow stress properties in the metal matrix. Bi-2223 grains are known to form at silver interfaces with c-directions normal to the local interface plane. Dense, textured Bi-2223 nucleates and/or grows faster and better in close proximity to silver. The interface plane can then be relied upon to assist in alignment of the Bi-2223 grains with their high current direction (a-b plane) along the direction of the filament and tape axis. Thus, by improving the quality of the silver-oxide interface, i.e., by providing a smooth interface, the incidence of silver-induced misaligned grain growth can be reduced. Overall Bi-2223 texture can be substantially improved by even a small reduction in the incidence of misaligned Bi-2223 grains because the area occluded by a misaligned grain is much larger than the volume it occupies in the filament.

In at least some embodiments, the oxide grains deviate from local interface planarity by less than about 10-12°. Grain-to-grain misalignment is less then 10-12° along the metal matrix-oxide filament in the direction of current flow. Alignment of about 10-12° is the level of orientation achievable by the Bi-2212 precursor oxide, which is then maintained through the process. Thus, in at least some embodiments, oxide grain orientation is maintained throughout processing of the oxide precursor into the final oxide superconductor.

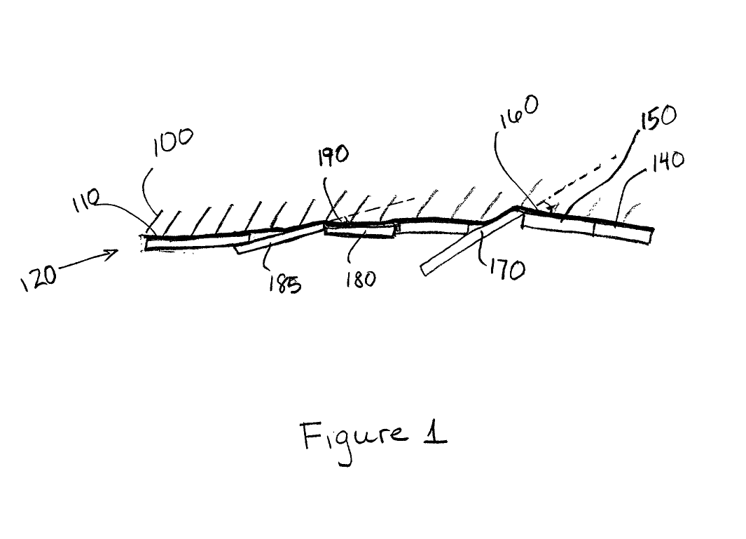

FIG. 1 is a pictorial illustration of a composite filament 120 having an oxide-metal matrix 100 interface 110 illustrating various types of grain-to-grain orientations in the oxide phase at the interface. Grain-to-grain orientation is determined by measuring the degree of deviation from planarity, as determined by a vector taken from the surface of the two grains in question. In an ideal situation, the oxide grains are perfectly aligned, in which case the degree of grain misorientation is zero. This is shown by oxide grains 140 and 150. The resultant oxide surface is very smooth. As is discussed in detail herein, the typical composites contain a high degree of misalignment between grains, which is depicted by grains 160 and 170. The interface exhibits local roughness and is characterized by a misalignment angle 160 which is greater than 10-12°. In contrast, in at least some embodiments of the present invention, the oxide filament surface contains grains which are closely aligned, that is, the grain-to-grain misalignment is less than or equal to about 12° or, in at least some embodiments less than or equal to about 12°. This is shown by oxide grains 180 and 185, which deviate from local planarity by the amount depicted by angle 190, i.e., a very few degrees.

The method of the invention may be used for the processing of both monofilament and multifilament composites. It is particularly useful in the preparation of fine multifilamentary composites in which there is a large filament surface-to-volume ratio, leading to high incidence of surface induced misaligned grain growth.

The oxide superconductor used in the preparation of the mono- or multifilamentary article may be is a member of the bismuth-strontium-calcium-copper-oxide family (BSCCO) of superconductors, in particular, Bi₂Sr₂Ca₁Cu₂Oₓ (Bi-2212) and Bi₂Sr₂Ca₂Cu₃Oₓ (Bi-2223). Particularly promising results are obtained when the bismuth is partially substituted by dopants, such as lead, e.g., (Bi,Pb)SCCO, and (Bi,Pb)_{2.1-2.3}Sr₂Ca₂Cu₃Oₓ. For the purposes the discussion herein, use of the term Bi-includes both the lead-doped and the lead free composition unless specifically stated otherwise.

In at least some embodiments, the final oxide superconductor is Bi-2223 and the oxide precursor is Bi-2212 and additional secondary phases, e.g., 0011, necessary to provide the proper overall stoichiometry for Bi-2223. Bi-2212 plus secondary phases is used precursor oxide in at least some embodiments because the grains of Bi-2212 are readily densified or textured using conventional processes. It is recognized however that other oxide precursors may be used in accordance with the method of the invention, so long as they are susceptible to texturing and can be converted into an oxide superconductor. Both the rare earth-barium cuprate (YBCO) and thallium-barium-calcium-cuprate (TBCCO) families of oxide superconductors include anisotropic oxide grains and so may be used in the present invention.

A mono- or multifilamentary oxide precursor may be made by any conventional method. For example, an oxide powder in tube (OPIT) method may be used according to the general description given by Sandhage et al. (supra) in which precursor compounds, such as oxides, salts or metallorganic compounds, are loaded into a metallic, e.g., silver, tube and sealed, and thereafter subjected to a heat treatment to obtain a precursor oxide, such as Bi-2212 and secondary 0011 phase. Alternatively, the precursor compounds may be prereacted to form Bi-2212 and secondary phases prior to loading into the metallic tube. The silver tube includes dissolved metal solutes, which are converted into finely dispersed oxide domains at the appropriate point in the process to increase the flow stress of the silver matrix.

Alternatively, a metallic powder in tube (MPIT) process may be used in which metal or alloy powders are used to form the Bi-2212 precursor. See, Otto et al. “Properties of high Tc wires made by the metallic precursor process”, JOM, 45(9):48 (September 1993), for further details. The metal sources are added in proportions substantially stoichiometric for the final oxide superconductor. Additional noble metal may be added on the order of 0-70 wt %. Further detail on the processing of multifilamentary oxide superconductor composites may be found in International Application No. WO 99/07004, published Feb. 11, 1999, and entitled “Fine Uniform Filament Superconductor”, the contents of which are hereby incorporated by reference.

The tube is then extruded into a wire of smaller dimension. In the case of a multifilamentary wire, and the extruded wire is then repacked into another metallic tube and extruded again to obtain a multifilament of reduced cross-section. The process of repacking and extruding the multifilamentary wire is carried out until the desired number of filaments is attained and at least one dimension of each filament has obtained the desired dimension (typically a function of the oxide grain length). The multiple application of mechanical forces on the silver matrix during this process increases the flow stress of the matrix in a process known as work hardening.

Bi-2212 may be prepared having either an orthorhombic or tetragonal solid-state lattice symmetry. In at least some embodiments, it may be desirable to use the tetragonal phase of the Bi-2212 oxide superconductor in the formation of the multifilament wire, because it has been observed previously that tetragonal Bi-2212 performs well in wire forming operations. This may be because the tetragonal phase, having identical a and b axes, responds better to more symmetric deformations and/or because the packing density of the tetragonal phase of Bi-2212 is greater than the corresponding orthorhombic phase. The tetragonal phase therefore packs well into the metallic tubes used in the OPIT process to form homogeneously packed powders which can be further densified upon extrusion or drawing. The orthorhombic phase of Bi-2212, on the other hand, undergoes densification or texturing to a much greater extent than the corresponding tetragonal phase, resulting in a denser, less porous oxide grains structure when subjected to asymmetric deformation operations. Thus, in at least some embodiments, a filamentary wire is formed using tetragonal phase Bi-2212, which is phase converted into orthogonal phase Bi-2212 prior to texturing. See, U.S. Pat. No. 5,942,466, entitled “Processing of (Bi,Pb)SCCO Superconductors in Wires and Tapes,” the contents of which are incorporated by reference, for further details.

According to the method of the invention, a multifilamentary article containing the precursor to an oxide superconductor is processed to obtain a highly textured grain structure. The precursor to the oxide superconductor is selected for its ability to be oriented or textured. Bi-2212 in particular may be textured using a variety of techniques. For example, texture may be introduced by reaction conditions and/or deformation. In reaction-induced texture (RIT), processing conditions are chosen which kinetically favor the anisotropic growth of the oxide grains. Reaction-induced texture can occur in a solid phase system or in a solid-plus-liquid phase system. Bi-2212 undergoes a reversible melt at elevated temperatures, which is well suited for RIT. An anneal in the range of 800-860° C. in 0.075 atm O₂ (total pressure 1 atm) is typical for partial melting to occur. The presence of a liquid greatly increases the kinetics of anisotropic grain growth, probably through increased rates of diffusion of the oxide components. Deformation-induced texture (DIT) occurs by applying a strain to the oxide grains to induce alignment of the oxide grains in the plane or direction of elongation. Deformation-induced texture requires anisotropic grains in order to effect a preferential alignment of the grains. Orthorhombic Bi-2212 may b used in at least some embodiments as the oxide precursor for deformation-induced texturing. Suitable texture-inducing deformations include asymmetric deformations, such as rolling and pressing. One or more anneal-deformation iterations may be performed.

In a at least some embodiments, a high reduction rolling process is used to highly texture the multifilamentary article. A high reduction rolling operation has been shown to be highly effective in producing a high density, highly textured oxide phase. The single deformation step introduces a high level of deformation strain, e.g., 40-95%, and, in at lest some embodiments, 60-83% strain, by reducing the article thickness by 40-95% in a single step. The high reduction process completely distributes the deformation energy throughout the article. Thus, the entire filament experiences similar densitying and texturing forces, leading to greater filament uniformity and degree of texture. Such processing additionally has been found to eliminate undesirable non-uniformities along the length of the oxide filaments, while providing consistently better electrical transport properties in the final article, regardless of the particular method used to obtain the final oxide superconducting phase. It is particularly useful in preventing sausaging of the oxide filaments. As a further advantage, the process provides a densified and textured precursor oxide in a single anneal and deformation step, as compared to more traditional methods of precursor processing which involve multiple anneal and deformation steps. Due to the fine grain (e.g., less than one micron) structure of the precursor oxide and the high flow stress of the work hardened silver matrix, there is no significant flow of silver into the oxide filaments during texturing deformation. Further information on a single step deformation process may be found in U.S. Pat. No. 6,247.224, entitled “Simplified Deformation-Sintering Process for Oxide Superconducting Articles,” which is hereby incorporated by reference.

The textured oxide precursor composite is then heat treated to convert the metal solutes of the silver matrix into oxides so as to form an ODS silver having a high flow stress. In such an exemplary process, the composite is heated at temperatures in the range of 200-450° C. under oxidizing atmospheres.

In at least some embodiments, the silver matrix is oxidized without altering the composition of the precursor oxide. Relatively low temperature, high-oxygen pressure processes have been reported for oxidizing metal precursors within silver. The process has the advantage of controlling the diffusivity of the predecessor metal so as to limit its diffusion into the surrounding metal matrix, which helps promote a dense oxide layer. See, U.S. Pat. No. 5,472,527, entitled “High Pressure Oxidation of Precursor Alloys,” for further detail. In such an exemplary process, the strand is heated at temperatures in the range of 200-300° C. under oxygen partial pressures in the range of up to about 500 atm.

The high flow stress precursor oxide composite then is heat treated to form the final oxide superconductor. In at least some embodiments, phase conversion is carried with mechanical constraint of the composite so that porosity does not develop. During high temperatures required for phase conversion, the silver is annealed and would flow readily into any available interfacial pore spaces. By modification of the silver matrix prior to annealing at high temperatures in conjunction with steps taken to both decrease oxide dilation and decrease oxide compression stress, material flow of the silver into the oxide filament is substantially reduced or eliminated and a smooth silver-filament interface is obtained.

In another embodiment, phase conversion is carried out with or without mechanical constraint to obtain a partially reacted oxide filament composite. Intermediate deformation is performed to densify the oxide core, as is describe above. Heat treatment is then continued to complete oxide superconductor formation.

In at least some embodiments, processing of the Bi-2212 (plus secondary phases) precursor into Bi-2223 is accomplished under conditions that partially melt the oxide such that the liquid co-exists with the final oxide superconductor. During the partial melt, non-superconducting material and precursor oxide phases melt and the final oxide superconductor is formed from the melt. The heat treatment thus is conducted in two steps, in which (a) a liquid phase is formed such that the liquid phase co-exists with the final oxide superconductor; and (b) the liquid phase is transformed into the final oxide superconductor.

The above process has been found to advantageously heal any cracks or defects that may have been introduced into the oxide superconductor filaments, particularly during any deformation operation. The liquid is believed to “wet” the surfaces of cracks located within and at the surfaces of the oxide grains. Once the conditions are adjusted to transform the liquid into the final oxide superconductor, oxide superconductor is formed at the defect site and “heals” the defect. In an exemplary method, the processing conditions are first adjusted to bring the article under conditions where a liquid phase is formed. It is desired that only a small portion of the oxide composition be transformed into a liquid so that the texturing introduced in previous steps is not lost. In the BSCCO system, in general a temperature in the range of 815-860° C. may be used at a P_{O2} in the range of 0.001-1.0 atm. In at least some embodiments, conditions of 820-835° C. at 0.075 atm O₂ are sufficient. The processing parameters may then be adjusted to bring the article under conditions where the liquid is consumed and the final oxide superconductor is formed from the melt. In general, a temperature in the range of 780-845° C. may be used at a P_{O2} in the range of 0.01-1.0 atm. In at least some embodiments, a condition of 820-790° C. at 0.075 atm O2 is sufficient. See, U.S. Pat. No. 5,635,456, entitled “Processing for Bi/Sr/Ca/Cu/O-2223 Superconductors,” which is hereby incorporated by reference, for further details.

In addition, the article possesses highly dense, highly textured oxide superconductor filaments, which are characterized by an absence of misaligned Bi-2223 grains. The filamentary composites demonstrate good electrical transport properties, as is demonstrated in the Example.

The invention is described in the following examples, which are presented for the purpose of illustration and which are not limiting of the invention, the full scope of which is set forth in the claims.

Mono and multi filament Bi-2223 wires were made with high-flow stress oxide dispersion strengthened (ODS) silver alloy throughout. Six monofilament billets were made with different sheath Mg levels and fill factors as described in Table 1.

TABLE 1
Mono-filament billets fabricated for the example

| | Wt % | Billet Dimensions (inches) | | | | Estimated Bi-2223 |
|---|---|---|---|---|---|---|
| ID # | Mg | OD | ID | Depth | Length | fill factor |
| F50a1 | 0.21 | 0.75 | 0.469 | 4.5 | 6.0 | 25 |
| F50a2 | 0.21 | 0.75 | 0.625 | 4.5 | 6.0 | 45 |
| F50b1 | 0.40 | 0.75 | 0.469 | 4.5 | 6.0 | 25 |
| F50b2 | 0.40 | 0.75 | 0.625 | 4.5 | 6.0 | 45 |
| F50c1 | 0.60 | 0.75 | 0.469 | 4.5 | 6.0 | 25 |
| F50c2 | 0.60 | 0.75 | 0.625 | 4.5 | 6.0 | 45 |

The billets were cleaned and packed with standard precursor powder to Bi-2223. The ends of the billets were fitted with a cap and stem, followed by welding and evacuation to remove gases. The stems were crimped and the billets drawn many times consecutively to form wires in the diameter range of 0.01″ to 0.05″. Intermediate anneals were completed in an inert atmosphere in order to ensure that the Mg within the alloys would not be oxidized.

The 0.025″ diameter wires made by the above method were processed through final heat treatment. In each case, some wire samples were subjected to annealing and oxidation after drawing, followed by rolling to different strain levels. The wires were then subjected to the standard first heat treatment that forms some Bi-2223. The intermediate roll deformation (“ISR”) step was then applied to different strain levels (0% through 20%), followed by standard final heat treatment to complete Bi2223 formation and sintering. Some samples were also pressed rather than rolled, as noted in Table 2. In some cases, the samples were “pack” rolled between plates of steel to simulate large diameter rolls, while others were rolled with 4″ diameter rolls (“bare”).

After completion of Bi-2223 formation, samples were tested for Ic, and microstructures. Interface smoothness of select samples were evaluated via image analysis.

Samples were also made without ISR, rather, with samples pressed in situ. The mechanical constraint method consisted of ˜5 cm×8 cm INCONEL high temperature alloy plates with screws tightened to specific torque levels that generate compression in the tapes between the plates as shown in FIG. 6 (pressure between 30 atm and 500 atm). Oxygen permeable aluminum oxide matting (“Saffil”) was used as an interlayer on either side of the wire samples so as to prevent wire sintering to the plates and provide the stack with mechanical compliance. With the matting acting as a compressive medium, the wires remained at or near the compressive stress levels generated by the ambient temperature torque-down of the screws.

Prior to the first heat treatment that forms Bi2223, the samples were placed between the mechanical constraint plates and the screws tightened to various torque and corresponding compressive stress levels. After full reaction without ISR, the screws were removed, the plates separated, and the matting brushed away to allow Ic and other characterization.

Monofilament Je levels in excess of typical rolled mono levels were attained (Table 2). Typical relationships between Je, intermediate strain, anneal versus no anneal, and rolling versus pressing are illustrated in FIG. 8 and reported in Table 2. Similar results were obtained with multi-filament wires. Je at 77 K, self field, 1 V/cm criterion are the average of multiple samples and tests. “Roll” compression refers to the use of an ISR step. “Press” compression refers to use of mechanical constraint.

TABLE 2
Summary of transport results with ambient temperature rolled & pressed
mono wires with high deformation stress Ag - Mg sheathing.

| | | | | ISR | ISR strain | | |
|---|---|---|---|---|---|---|---|
| Wire | Diameter | Precursor rolled | Anneal | compressor | at max Je | Max Je | Max Jc |
| ID | (inches) | size (inches) | treatment | type | (%) | (kA/cm2) | (kA/cm2) |
| F50a1 | 0.025 | 0.0076 × 0.055 | Yes | Roll | 20 | 7.3 | 29.2 |
| ″ | ″ | ″ | ″ | Press | 5 | 4.6 | 18.4 |
| ″ | ″ | 0.0052 × 0.075 | No | Roll | 20 | 6.2 | 24.8 |
| ″ | ″ | ″ | ″ | Press | 6 | 2.9 | 11.6 |
| ″ | ″ | 0.0041 × 0.089 | ″ | Roll | 10 | 3.8 | 15.2 |
| F50b1 | ″ | 0.008 × 0.055 | Yes | Roll | 5-10 | 5.0 | 20.0 |
| ″ | ″ | ″ | ″ | Press | 20 | 4.8 | 19.2 |
| F50b2 | ″ | 0.0073 × 0.057 | No | Roll | 13.5 | 6.2 | 14.4 |
| ″ | ″ | ″ | ″ | Press | 19 | 6.4 | 14.9 |
| ″ | ″ | 0.0071 × 0.059 | ″ | Roll | 19 | 6.7 | 15.6 |
| ″ | ″ | ″ | ″ | Press | 18.5 | 6.2 | 14.4 |
| F50c2 | 0.033 | 0.0125 × 0.043 | ″ | Roll | 7-20 | 4.6 | 10.7 |
| ″ | ″ | ″ | ″ | Press | 16 | 5.2 | 12.1 |

In agreement with the hard sheath/improved stress transfer model, higher ISR strains provided higher Jc levels. Clearly, the Jc responded well within the hardened sheathing of these samples. In general, the higher Jc levels were attained in rolled samples rather than pressed samples. These results show that there is considerable Jc potential in engineering the hardness of the sheath to exceed the hardness of the filaments, but excess alloying material can compromise Je/Jc.

It is clear in FIG. 8 that large Ic gains occur by going to even larger ISR reductions with high flow stress sheath than the ˜20% maximum investigated. In particular, through repeated straightforward optimization Je levels of up to 20 kA/cm2 are feasible with these samples.

what is claimed is:

1. A method of making an oxide superconductor article, comprising:
providing an oxide filament comprising a textured oxide superconductor precursor having an effective oxide flow stress, σ_{c}, in a silver-based matrix;
converting the textured oxide superconductor precursor into an oxide superconductor; and
during precursor conversion, applying a compression stress to the oxide filament which is equal to or greater than the oxide flow stress σ_{c}, the silver-based matrix having a flow stress, σₛ, whereby σₛ>σ_{c} under conditions of phase conversion so that material flow between the silver-based matrix and the oxide filament is substantially avoided.

2. A method of making an oxide superconductor article, comprising:
providing an oxide filament comprising a textured oxide superconductor precursor having an effective oxide flow stress, σ_{c}, in a silver-based matrix;
converting at least a portion of the textured oxide superconductor precursor into an oxide superconductor, whereby porosity is introduced into the oxide filament; and
applying a compression stress to the oxide filament that is greater than the oxide flow stress, σ_{c}, to densify the porous oxide superconductor,
whereby σₛ>σ_{c} under densifying conditions so that material flow between the silver-based matrix and the oxide filament is substantially avoided.

3. The method of claim 1 or 2, further comprising the step of:
before or during precursor conversion, converting the silver-based matrix into a matrix having a selected flow stress, σₛ, greater than that of pure silver.

4. The method of claim 1, further comprising:
after phase conversion of at least a portion of the precursor to the oxide superconductor, applying a compression stress to the oxide filament that is greater than the oxide flow stress, σ_{c}, to densify the oxide superconductor.

5. The method of claim 1, wherein the applied compression stress at least matches an expansion force experienced by the textured oxide superconductor precursor during conversion to the oxide superconductor.

6. The method of claim 1, wherein the flow stress of the silver-based matrix is obtained by formation of strengthening agents which increase the flow stress, σₛ, of the material over that of pure silver.

7. The method of claim 6, wherein the strengthening agents comprise fine oxide particles.

8. The method of claim 3, wherein said silver-based matrix comprises a silver alloy comprising solute metals.

9. The method of claim 8, wherein the step of converting the silver-based matrix into a matrix having a selected flow stress, σₛ, comprises oxidizing the solute metals into metal oxides, particles within the silver matrix.

10. The method of claim 9, wherein oxidizing is carried out at a temperature in the range of 200-450° C. in an oxidizing atmosphere.

11. The method of claim 9, wherein oxidizing is carried out at a temperature in the range of 200-300° C. in an oxygen partial pressure in the range of up to about 500 atm.

12. The method of claim 8, wherein the solute metals are selected from the group consisting of aluminum and magnesium.

13. The method of claim 8, wherein the solute metal is present in an amount in the range of about 0.01 wt % to about 1.5 wt %.

14. The method of claim 1 or 2, wherein the compression stress applied to the precursor comprises uniaxial pressing.

15. The method of claim 1, wherein the compression stress comprises a mechanical constraint.

16. The method of claim 15, wherein the silver-based matrix comprises a solute metal in the range of about 1.5 wt %.

17. The method of claim 15, wherein the step of applying a mechanical constraint comprises positioning the oxide filament between opposing surfaces to provide a compressive force.

18. The method of claim 15, wherein the step of applying a mechanical constraint comprises co-winding the oxide filament with an elongated element, said elongated element wound under tension to provide a compressive force.

19. The method of claim 15, wherein the compression stress applied to the precursor comprises hot isostatic pressing (HIPing).

20. The method of claim 19, wherein the HIPing force is in the range of 10 to 2500 atm.

21. The method of claim 20, wherein the HIPing force is in the range of 25 to 250 atm.

22. The method of claim 2, wherein the compression stress applied to the precursor comprises rolling.

23. The method of claim 22, wherein the silver-based matrix comprises a solute metal in the range of about 0.01-0.5 wt %.

24. The method of claim 22, wherein the rolling compression results in a 5-20% reduction in thickness of the article.

25. The method of claim 1, wherein the density of the oxide superconductor precursor is substantially retained during conversion to the oxide superconductor.

26. The method of claim 1, wherein the texture of the oxide superconductor precursor is substantially retained during conversion to the oxide superconductor.

27. The method of claim 1 or 2, wherein the precursor oxide comprises Bi-2212, and the final oxide superconductor comprises Bi-2223.

28. The method of claim 1 or 2, wherein the precursor is textured using asymmetric deformation.

29. The method of claim 28, wherein the asymmetric deformation is selected from the group consisting of rolling and pressing.

30. The method of claim 29, wherein the rolling deformation results in a 40-95% reduction in thickness of the article.

31. The method of claim 1 or 2, wherein the precursor is textured using reaction-induced texturing.

32. The method of claim 1 or 2, wherein the precursor comprises Bi-2212 and reaction induced texturing is conducted at a temperature in the range of 800-860 C and an oxygen partial pressure in the range of 0.01-1.9 atm.

33. The method of claim 1 or 2, wherein Bi-2212 is converted into Bi-2223 in a two-step heat treatment in which the precursor is heated under conditions which form a liquid phase in co-existence with Bi-2223 and then the precursor is heated under conditions which transform the liquid phase into Bi-2223.

34. A Bi-2223 oxide superconductor article comprising:
at least one oxide superconducting filament in a silver-based matrix, wherein the matrix-filament interface has an average deviation from planarity of less then 10° along the length of the filament.

35. The article of claim 34, wherein the filament length is at least one cm

36. The article of claim 34,wherein the filament length is at least 10 cm.

37. The article of claim 34, wherein the filament length is at least 100 cm.
